(19) United States
(12) Patent Application Publication
(10) Pub. No.: US 2005/0233485 A1
(43) Pub. Date: Oct. 20, 2005

(54) Light emitting diode package with self dosing feature and methods of forming same

(76) Inventors: Alexander Shishov, Bykovo (RU); Dmitry Agafonov, Moscow (RU); Nikolai Scherakov, Moscow (RU); Vladimir Abramov, Moscow (RU); Valentin Scherbakov, Moscow (RU)

Correspondence Address: Joseph Page, PO Box 757, La Jolla, CA, 92038, US

(21) Appl. No.: 11/144,084

(22) Filed: Jun. 6, 2005

Related U.S. Application Data
(63) Continuation of application No. 10/393,337, filed on Mar. 20, 2003.

(51) Int. Cl. H01L 21/00

(52) U.S. Cl. 438/25; 438/27; 438/29

(57) ABSTRACT

Light emitting diodes are prepared with specialized packages which provide a dosing feature with respect to a phosphor wavelength converting medium. Elements of the device package form a specially shaped cavity when coupled together. The shape and size of the cavity operates to control the dosing of phosphor spiked medium of soft gel. The gel fills the cavity such that light emitted from a semiconductor die is exposed to a similar cross section independent of the exact direction of light propagation. In this way, ‘white’ LED systems are formed from blue emitting diodes as highly controlled phosphor dosing permits precise amounts of blue light to be converted to yellow light without problems with angular uniformity observed in competing technologies.

This application is a continuation application which continues from application having Ser. No. 10/393,337, filed Mar. 20, 2003, still pending.

### BACKGROUND OF THE INVENTIONS

1. Field

The following invention disclosure is generally concerned with packaging for light emitting semiconductor devices, sometimes ‘LED’s, and specifically concerned with packages which provide a dosing function with respect to a wavelength shifting medium.

2. Prior Art

Light emitting diodes LED are highly reliable and inexpensive sources of light. However, the very nature of an LED suggests that light emitted therefrom is concentrated in wavelength about a particular ‘line’. That is, an LED is necessarily of one particular color or another determined by its physical composition.

There is however great demand for a ‘white’ LED. White light is comprised of multiple wavelengths of the visible spectrum. Thus, a ‘white’ LED must produce light on a plurality of lines. One common way to achieve a white light LED is to create an LED having a design wavelength of high energy blue light. Then, to use some of the blue light in a conversion process which results is some of the energy being transfer into light of other colors (wavelengths). This is readily possible via a material such as certain phosphors. Some of the blue light is absorbed and excites the phosphor which then re-emits at a longer wavelength, i.e. yellow or red light. When viewed, such an LED appears white because it seems to emit with blue light and with yellow light simultaneously.

In systems employing phosphors to convert blue light in this way, the phosphor is typically applied directly to the exterior of the LED semiconductor. A phosphor is ground into fine powder and mixed with a binder such as epoxy and applied directly to the semiconductor die. Light from the semiconductor leaves the die and enters the epoxy spiked with phosphor. Depending upon the density of the phosphor in the epoxy, and the thickness of the epoxy/phosphor conversion layer, an ‘interaction cross section’ is implied. Thus, the degree to which blue light is converted to other colors depends on the density of the phosphor as well as the geometry of the conversion layer.

Pioneers in this field note great difficulty in producing white light having angular uniformity. Indeed, for each propagation direction in the emitted beam, a different color temperature is found. This is due to the fact that the path of the light from the semiconductor, through the LED optics system, and into an output beam, is different for all emission directions. More particularly, light passing through the conversion layer may have different interaction cross sections associated therewith for each propagation direction. Great efforts have been made to reduce the angular dependence of color temperature in packages arranged for ‘white’ light LED systems.

For example, inventor Ng teaches in European patent application EP 1,179,858 A2, a technique and arrangement which causes applied wavelength conversion layers to produce more even color temperature with respect to emission direction. However, great difficulties remain in these systems. Namely, surface tension variances depend on factors such as ambient temperature, shape and size of a chip, size of reflector cup and concentration of phosphor in epoxy, among others. It is therefore impossible to achieve the constant thickness in a large quantity of LED devices. Thus the device/device consistency is low. Further, problems with trapping bubbles within the conversion layer, and between the conversion layer and the chip or reflector cup all contribute to poor performance.

Accordingly, other inventors have attempted solutions which do not have these problems. For example, inventor Lowery presents a teaching in U.S. Pat. No. 5,959,316 which has a very uniform conversion layer. However, this system fails to deliver good result because it assumes that the concentration of light emitted from the chip in all directions is uniform; an assumption which is not precisely correct. In addition, there remains great difficulty in producing the conversion layers described as they are highly regulated in shape and thus require supporting apparatus and methods to produce them with uniformity.

Finally, systems proposed in U.S. Pat. No. 6,252,254 similarly address the angular dependence of color temperature in white LED devices. Again, a conversion layer is applied to a semiconductor die to shift the wavelength of light produced in the chip. This system also suffers from difficulty in construction with regard to providing a uniform and controlled conversion layer in particular regard with respect to shape and more particularly with regard to interaction cross section. Thus, light produced in these devices have a color temperature which varies as a function of emission angle in the output beam.

Certain concepts commonly owned and taught by present inventors include those of U.S. application Ser. Nos. 10/216,275; 10/360,955; 10/360,239; and 10/081,008 include portions of systems which may be integrated and cooperate with the novel arrangements taught here. Therefore, these disclosures are hereby incorporated by reference as if there were reprinted here in their entirety.

While systems and inventions of the art are designed to achieve particular goals and objectives, some of those being no less than remarkable, these inventions have limitations which prevent their use in new ways now possible. These inventions of the art are not used and cannot be used to realize the advantages and objectives of the present inventions.

### SUMMARY OF THESE INVENTIONS

Comes now, Shishov, A.; Agafonov, D.; Scherbakov, N.; Scherbakov, V.; and Abramov, V. with inventions of light emitting diode packages having self dosing features with respect to wavelength conversion layers including devices and methods. It is a primary function of these systems to provide angular uniformity with respect to color temperature. It is a contrast to prior art methods and devices that those systems do not provide packages with wavelength conversion layers having effective dosing means.

Devices and systems are presented here which yield improved white LEDs having low color temperature variance over a predefined angular range. A very special package includes a scheme to provide precision dosing with respect to a wavelength shifting mechanism. Media are provided with special composition, shape and size to cooperate with the task of making a white LED with even color temperature over an angular distribution.

To effect such a precise wavelength shifting medium having said highly controlled function, the size and shape, or ‘dosing’, of the wavelength shifting medium must be precisely controlled. Further, manufacturing control must be excellent with particular regard to piece-to-piece uniformity. It was shown above that wavelength shifting media which are applied as sprays, liquids, coatings, et cetera, are applied without means to accurately form the medium in a manner to support angular invariance of color temperature.

Systems of these inventions result in precision white light LEDs having output beams with low angular variance of color temperature. Although wavelength shifting media are not directly applied with a particular shape, applied media are finally shaped by mechanical cooperation with the underside surface of a cover element. A semiconductor die is placed onto a substrate or base element in the fashion common in the art with appropriate electrical connections. To that, a measured amount of a specially prepared soft pliable gel may be applied. Further, a cover element having a undersurface of prescribed shape is pushed onto the base—semiconductor—gel combination and affixed thereto. The act of pushing the cover to the base causes the gel to be displaced and pushed about to completely fill a cavity formed between the base and the cover. In this way, a precisely shaped wavelength conversion medium is formed. The shape operates to cause the wavelength conversion medium to interact with light traveling in various direction to be exposed to a similar interaction cross section. Thus, no matter which direction light is emitted from the semiconductor chip, that light experiences about the same amount of wavelength conversion activity. Light emitted in all directions therefore is comprised of about the same amount of blue and yellow light to yield a uniform color temperature.

### OBJECTIVES OF THESE INVENTIONS

It is a primary object of these inventions to provide high performance white LED devices.

It is an object of these inventions to provide LED packages with advanced wavelength conversion layers.

It is a further object to provide white LED systems having low variance of color temperature as a function of emission direction in the output beam.

A better understanding can be had with reference to detailed description of preferred embodiments and with reference to appended drawings. Embodiments presented are particular ways to realize the invention and are not inclusive of all ways possible. Therefore, there may exist embodiments that do not deviate from the spirit and scope of this disclosure as set forth by the claims, but do not appear here as specific examples. It will be appreciated that a great plurality of alternative versions are possible.

### BRIEF DESCRIPTION OF THE DRAWING FIGURES

These and other features, aspects, and advantages of the present inventions will become better understood with regard to the following description, appended claims and drawings where:

FIG. 1 is cross sectional view of a first version of these inventions;

FIG. 2 illustrates a similar view of another version;

FIG. 3 is an exploded view of an LED package showing various elements thereof;

FIG. 4 illustrates a step in a process used to form LED packages of these inventions;

FIG. 5 similarly shows a following step in the same process;

FIG. 6 illustrates a final step in the process;

FIG. 7 is an cross section diagram of a finished result of the process; and

FIG. 8 illustrates an indexing and mechanical interlock coupling system.

### GLOSSARY OF SPECIAL TERMS

Throughout this disclosure, reference is made to some terms which may or may not be exactly defined in popular dictionaries as they are defined here. To provide a more precise disclosure, the following terms are presented with a view to clarity so that the true breadth and scope may be more readily appreciated. Although every attempt is made to be precise and thorough, it is a necessary condition that not all meanings associated with each term can be completely set forth. Accordingly, each term is intended to also include its common meaning which may be derived from general usage within the pertinent arts or by dictionary meaning. Where the presented definition is in conflict with a dictionary or arts definition, one must use the context of use and liberal discretion to arrive at an intended meaning. One will be well advised to error on the side of attaching broader meanings to terms used in order to fully appreciate the depth of the teaching and to understand all the intended variations.

LED Package

An ‘LED package’ is the electrical and mechanical support apparatus associated with (a) light emitting diode(s). Typically, such a package includes systems to provide mechanical stability, electrical connection; thermal management, and optical focusing subsystems.

Indexing Means

Indexing means includes mechanical systems arranged to align a plurality of parts with respect to a common axis such that the parts may better cooperate with one another.

Coupling Means

Coupling means includes those systems which connect, affix and hold together two or more parts. In some versions, coupling means are combined with indexing means in a single dual function system.

For purposes of this disclosure fill meaning of the noun: “indexing means”, which is functional in nature, may be more readily appreciated in view of the following note:

Indexing Means

An indexing means is a system arranged to align two or more parts together. In many embodiments of these inventions indexing means is a peg and hole pair. Many forms of alternate indexing means may be used to accomplish the identical task. The particular indexing means employed may be chosen for a particular task at hand, for example a peg and hole system might not be appropriate for a certain LED package, so in that case an alternative indexing technique may be preferred. The essence of the invention is not changed by the particular choice of indexing means. Therefore versions of these inventions should not be limited to one particular type of indexing means. The limitation described by ‘indexing means’ is met when the function is realized. Therefore, by use of the term “indexing means” it is meant that any conceivable means for mechanically aligning two or more of the package parts. Experts will recognize that there are many thousands of possible ways of providing an indexing means and it will not serve a further understanding of these inventions to attempt to list them here. The reader will appreciate that the broadest possible definition of “indexing means” is intended here.

Terms which are functional in nature like those above may be used throughout this disclosure including the claims. For example, ‘means for’ or ‘step for’ followed by a phrase describing a function. One should remain aware that any particular means which may be later provided as an example is not meant to limit the ‘means for’ to that example but rather the example is provided to further illustrate certain preferred possibilities. Thus the ‘means for’ or ‘step for’ should not be limited to any particular structure which may be called out but rather to any conceivable means of causing the function described to be effected. The reader will recognize it is the function to be carried out which is the essence of these inventions and many alternative means for causing those functions to occur may exist without detracting from any combination or combinations taught as part of these inventions.

### PREFERRED EMBODIMENTS OF THE INVENTIONS

In accordance with each of preferred embodiments of these inventions, there are provided LED package apparatus and methods of dosing a wavelength shifting medium. It will be appreciated that each of these embodiments described include both apparatus and method and that apparatus and method of one preferred embodiment may differ from the apparatus and method of another embodiment.

LED packages of these inventions provide means for dosing a wavelength conversion medium. This is done with particular regard to the fact that light emanating from a diode semiconductor die propagates in all directions. For each path from a semiconductor junction, through a wavelength conversion medium and further through an optical systems which redirect propagation direction, the amount of wavelength conversion is desired to be similar. Since light coupled into an output beam at a particular angle may travel many paths through the device package, it is actually the integral of all such paths compared to the integral of all such paths associated with another angle which should be similar. In this way, one is guaranteed a uniform color temperature over a design angular distribution.

To achieve this, a package with a purpose formed cavity is proposed. An LED package may be comprised of a semiconductor, a base element, electrical connections, and a lens. Further, these device packages might include a cavity formed between the cover element and the base element. Most common LED packages do not have such cavity, but rather the lens/cover is formed of a polymer material poured over and in intimate contact with the semiconductor. Some specialty LED packages include a cavity between the cover and the base. The semiconductor resides within the cavity. Sometimes a material having high thermal coupling and preferred expansion properties may also reside within the cavity. In these inventions, a medium such as a soft gel is used. Further, the soft gel serves as a binder or carrier into which a certain wavelength shifting composition is mixed. For example, a phosphor power may be finely ground and mixed into a soft gel which holds the phosphor in a uniform distribution. A carefully measured portion of gel/phosphor mix, or hereafter, wavelength shifting medium, is put between a cover element and a base element. When the cover element and base element are mechanically coupled together an enclosed cavity contains the wavelength shifting medium. Further, and most importantly, since the cavity is designed with a precise shape, it forces the wavelength shifting medium to take the exact shape of the cavity. One will note the volume of the cavity and the measured amount of gel are nearly equal to provide best results.

As the cavity is defined by the surfaces of both the base and the undersurface of the cover element, the act of pushing the cover to the base forms the cavity. When the systems which index and couple the cover element to the base element are well designed, the act of pushing the cover to the base element serves to distribute the gel in a prescribed and precise fashion. The gel is squished about to completely fill the cavity. The cover, by way of its coupling means, for example a mechanical interlocking system, is firmly affixed to the base element. It may be further coupled by way of adhesives such as glue.

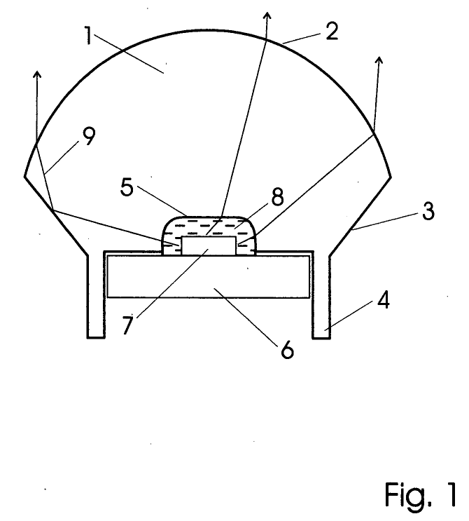

With reference to the appended drawing figures, one will appreciate a more complete understanding of these inventions. In particular, drawing FIG. 1 which illustrates a first preferred version. An LED package may include in part a cover element 1. Cover elements may be formed, for example, of molded polycarbonate or other hard plastic material having good optical transmission properties. These cover elements are formed with several important geometric features, each of which may have critical functionality with respect to these new concepts first taught here.

For example, the top surface 2 of the cover element may be formed into a lens. A simple convex lens is created when the top surface of the cover element includes a spherically shaped surface-air interface. Other types of lenses may include surface relief patterns to form diffractive elements such as a Fresnel lens. Optical energy within the plastic cover element which propagates towards the surface is coupled into an output optical beam. By careful alignment and design, the lens can form a concentrated and highly directional optical beam from a highly divergent source such as a diode semiconductor die.

These cover elements may also have another specialized surface which performs an optical function. A reflector element 3 may be formed about the sides of the device preferably in the shape of a conic section. This reflector element may be coated with a metallic material to promote reflection therefrom or its geometry may be arranged to support total internal reflection properties. Although preferred devices have reflectors made of conic sections, it is possible to make reflectors of spherical and aspherical shapes too. Indeed, reflectors may generally be considered a surface of rotation having an axial symmetry, the precise nature of the surface may be left to the discretion of a particular engineering design without deviation from the principles presented in this disclosure.

Cover elements of these inventions may also include indexing systems 4 whereby the cover element is aligned, coupled with, and held to, a base or substrate member. In the illustration, cover element legs 4 cooperate with the substrate as their spacing is precise with regard to the sides of the substrate. The legs may form a mechanical interlock in some versions. For example, small detents can be formed on the insides of the legs such that the detents engage the edges of the substrate and hold it to the cover element with precise alignment and solid force. Still further, other versions may include systems whereby legs are received in holes, precisely aligned and spaced, in a large substrate The skilled artisan will appreciate that indexing may be achieved in a great plurality of ways; that the cover is coupled to the substrate and aligned therewith is the basis of any of these indexing means.

Of primary importance, is the underside surface 5 of these cover elements. A cover element when pushed to the substrate forms a cavity between the cover element and the substrate. The precise shape of that cavity is partly defined by the undersurface of the cover element and that shape is of critical importance. By changing the shape of the undersurface of the cover element, one effectively changes the size and shape of a cavity formed when a cover element is pushed to and affixed with the substrate. To achieve the results described herein, the size and shape of the cavity is critical. By forming highly planned and regulated underside surfaces of cover elements, LED packages of these inventions are afforded a self dosing feature to control the distribution and density of a wavelength shifting medium. In this way, the emission characteristics of LEDs are precisely controlled.

Further, an LED package may include a base element 6. These base elements may be formed of common circuit board materials such as textilite or alternatives. In devices employing advanced heat management strategies, a metallic substrate may be used instead. In advanced versions like this, a substrate may have associated therewith an advanced and integral heat conductive path. Substrates may be quite small in size, i.e. sufficient to accommodate electrical connectors and mechanical coupling to a cover element. In other cases, a substrate may be quite large, having a surface area of several or tens of square centimeters. In these instances, a single substrate may be arranged to accommodate several cover elements and several semiconductor devices.

In addition, these devices include at least one light emitting diode semiconductor die 7. Preferred versions include the special high energy LED systems sometimes known as ‘blue’ LEDs. These high performance LEDs are preferably well coupled to the base with respect to thermal conduction. Some of these devices include a plurality of separate semiconductor die. Further, in some of those instances, the die may emit in various wavelengths, not all the same as other die in a single package.

These LED packages include a special wavelength shifting medium 8. This may be embodied as a soft and pliable gel material. A binder substance carries in a sort-of colloid mixture, a composition of phosphor powder in fine particles. The fine particles are uniformly distributed within the binder. When the package is assembled, the cover and base elements cause the gel to fill and precisely take the shape of the cavity. The gel serves a secondary function to further thermally couple and transmit heat away from the semiconductor die. The wavelength shifting medium nicely couples to undersurface of the cover element via contact to form a ‘clean’ optical joint. Similarly, the gel couples intimately to a die whereby a ray of light 9 produced in the die is easily transmitted into the wavelength shifting medium and further into the cover element. As the volume of the cavity is well known by careful design, the precise amount of gel is easily applied in predetermined amounts via automated machinery.

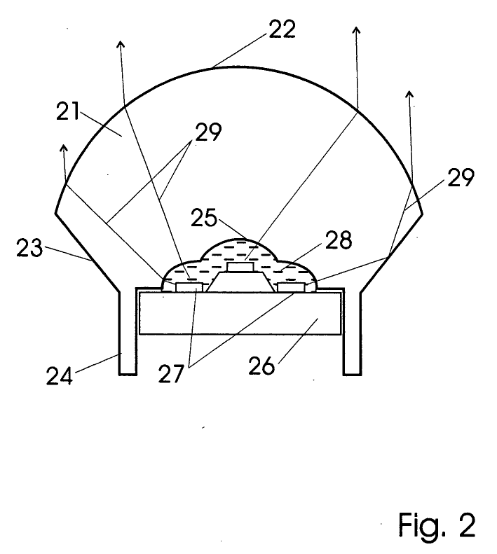

FIG. 2 illustrates another important version of these inventions. Where a plurality of semiconductor die are integrated into a single package system, it is the case that the undersurface of the cover element take a more complex shape. The contour of the undersurface may approximate the shape of the space occupied by the plurality of die. In essence, it is desirable that the distance between die and the cover element be about the same for light propagating in any direction. While this is not precisely possible, approximations provide excellent results. Light leaving the lens of the cover element in any particular direction is comprised of many rays having taken various paths in the phosphor wavelength conversion space. Because averaging is assured, nice even white light of a certain color temperature is emitted in all directions with little variation. This is quite unlike the art which finds great angular dependence with respect to color temperature. In the figure, cover element 21 includes a top surface 22 to form spherical (or more precisely, spherical section) lens, a conic section reflector 23, an indexing means 24. The undersurface 25 is not comprised of merely a single curvilinear surface, but rather one with discontinuities and multiple curved sections. When such a cover element is pushed to and coupled with a substrate 26, in encloses and protects a plurality of diode die 27 and a specially shaped cavity 28 is created to accommodate a soft flexible gel material spiked with a phosphor composition. Rays 29 propagating in various directions, each pass through the gel wavelength shifting medium and consequently interact with phosphor particles distributed therein. The interaction cross section is similar for each ray independent of its propagation direction while in the gel.

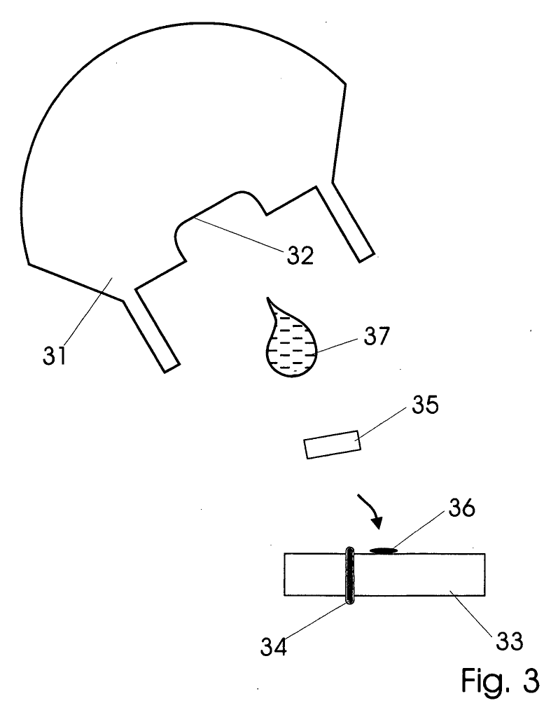

Methods of these inventions are nicely illustrated in FIGS. 3-7. Namely, a cover element 31 of transparent plastic having an undersurface 32 which forms a partial cavity in a shape which corresponds to the space which is occupied by a semiconductor die, is formed. A silicon semiconductor die 35 is bonded to a substrate 33 to form appropriate electrical connections 34 which may also include a second electrical contact to the top of said die. A soft pliable material 37, or ‘gel’, is prepared with a phosphor or phosphor like composition distributed uniformly therein. That same gel is put between the semiconductor die and the cover element. After, the cover element is pushed onto said substrate thereby causing said soft flexible material to take the shape of the cavity which encloses it and to come into intimate contact with the cover element and semiconductor die.

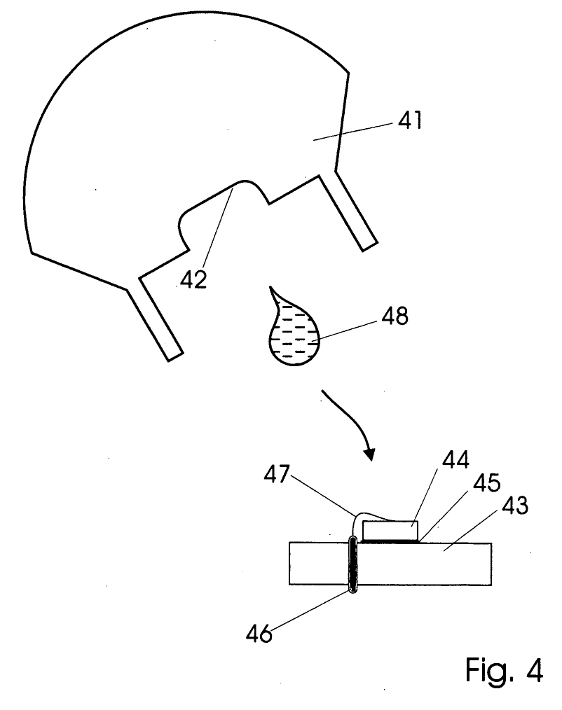

FIG. 4 better illustrates one version of the electrical connections which provide electrical service to the inside a LED package. The cover 41 with undersurface 42 is intended to couple with base 43 having thereon semiconductor die 44 which may be in good electrical and thermal contact via a solder joint 45 with the top surface of the base. An electrical via 46 and wire bond conductor 47 may be used to further electrically couple the die to energizing systems outside the cavity.

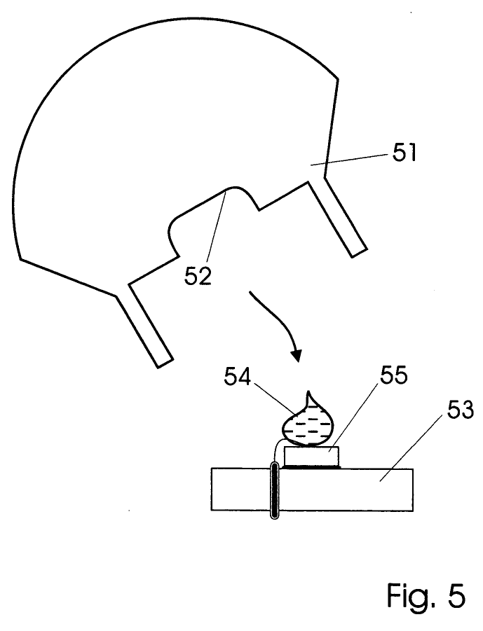

FIG. 5, shows how the gel may be applied directly to the top surface of a semiconductor die before a cover element is applied. A cover element 51 with specially shaped underside surface 52 arranged to accommodate a single element light emitter is to be applied to a base 53. Gel material 54 is put on the top of a semiconductor device 55.

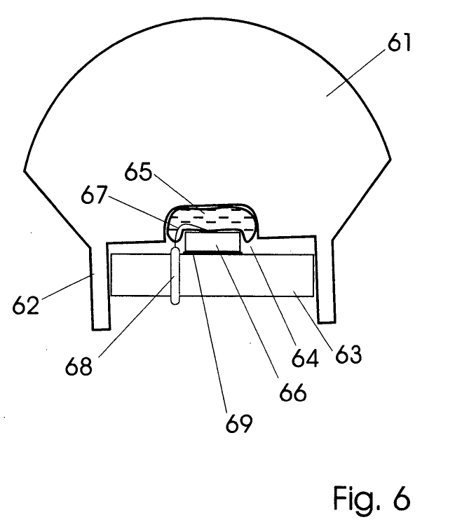

FIG. 6 illustrates how as a cover element 61 is applied and coupled by way of peg leg indexing means 62 with the base element 63, the gel 65 is forced about to fill the 5 cavity and envelope the semiconductor 66. Bipolar electrical contact is made via conductors 67, via 68 and bond 69.

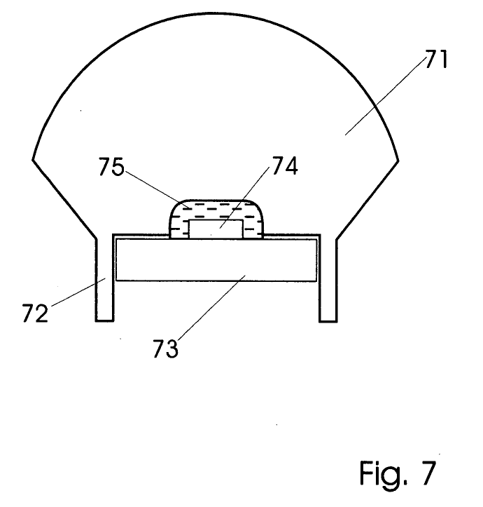

Finally, FIG. 7 shows the cover 71 being tightly fastened with pegs 72 to base 73. The semiconductor diode 74 is enclosed within the cavity and completely surrounded with an even layer of wavelength shifting media 75.

A special interest topic important in these inventions includes means of coupling a cover element with a base element. While skilled artisans will surely agree there are many possible mechanical systems which will serve equally well in holding a cover element affixed to a base element, they would also agree that it is impossible to enumerate them or illustrate each of them here. Accordingly, for purposes of providing a complete disclosure it is hereby stated that any mechanical system which affixes a cover element to a base element whereby a cavity is formed between them meets the spirit of the invention. Thus, one should not attempt to merely introduce a modification to the coupling means in belief such change would present a new device and invention; but rather, such effort would result in a version of these inventions taught here.

For completeness, an example of a preferred and best mode is illustrated to show one of the possible coupling systems. The reader will be reminded that alternatives which differ greatly from the example shown may be effective in providing acceptable versions all within the meaning of ‘coupling means’.

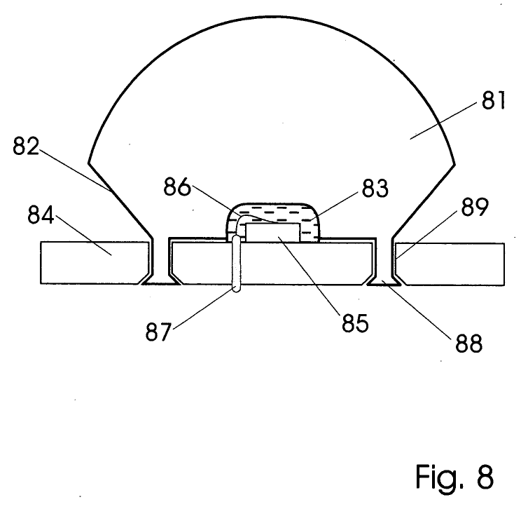

Thus, FIG. 8 shows a version of a cover element having a shaped undersurface which can be fastened to a base element to form a cavity therebetween. Like the previous drawings, the cover element 81 includes an integrated reflector 82. A cavity 83 is formed between the cover element and the base 84 when these pieces are merely brought together. Within the cavity, semiconductor die 85 may be disposed with electrical contacts thin wire 86 and via connector 87. Electrical contact of the opposite pole may be made on the surface of the base element. Cover element 81 may include combined indexing and coupling means comprising plastic pegs 88 and holes in base element 89. When the pegs which are formed integrally with the cover element, for example in a molding process, are pushed through the holes of the base element, an alignment is realized whereby the lens is caused to be precisely concentric with the semiconductor. In this way, the indexing functionality of the device is realized. The coupling function is further realized when the cover element is affixed to the base. This may be achieved via the melting of the peg ends into countersunk holes formed in the backside of the base element. A cover element pegs are set into holes of a base element and held there while heat is applied to the peg ends to cause them to melt and take the form of the countersunk holes. Melted peg ends provide resistance against the pieces being separated and thus a strong coupling is formed between them.

Drawings 1-7 are purposely left without detail as to coupling and indexing because it may be realized in many different efficient ways. For purposes of these inventions, when a specially shaped cavity which corresponds to regulating interaction cross section with respect to light propagating therethrough is formed as indexing and coupling systems are engaged, the essence is met.

The examples above are directed to specific embodiments which illustrate preferred versions of devices and methods of the invention. In the interests of completeness, a more general description of devices and the elements of which they are comprised as well as methods and the steps of which they are comprised is presented herefollowing.

Accordingly, these inventions include: light emitting articles having a cover element, a light emitting semiconductor, a base element, and a composition mixed into a soft and pliable binder material. The cover and base elements together form a cavity having a light emitting semiconductor with the phosphor and binder therein. These cover elements are typically a hard transparent plastic material such as polycarbonate sometimes formed in a molding process.

Such covers are affixed to a base element to form an LED package. The cover elements also include the following structures: a lens; a reflector, undersurface, and indexing means. Lenses may be a spherically shaped air/plastic interface. Alternatively, lenses may be diffractive in nature such as a Fresnel lens.

Reflectors of these articles are preferably surfaces of revolution having axial symmetry. One example of such surface of revolution includes a conic section. These reflectors may be comprised of a thin metallic layer on a surface of the cover element. In alternative versions, some reflectors operate under principles of total internal reflection. The reflectors may be disposed concentrically with respect to a lens and its undersurface.

The undersurface of cover elements and base elements together form cavities having a particular shape. Those shapes corresponds to the shape of space occupied by said at least one semiconductor. The undersurface may form a concave shaped space operable for receiving therein a gel material containing phosphor or other suitable wavelength shifting medium.

An indexing means provides alignment with respect to said cover element and said base element such that the lens is well coupled to the light emitting semiconductor to efficiently form an output beam. Articles having several semiconductors spatially removed from each other may form a diode array which occupies a space of particular form. The undersurface and base together form a cavity having a shape which corresponds to the shape of the space occupied by these semiconductors. In cases such as there, at least two of the semiconductors may be arranged to emit light of different wavelengths. The diodes may be positioned substantially in a planar field with some axial symmetry.

These inventions also include methods as follows. Methods of forming light emitting devices having the steps: forming a cover element having an undersurface which in cooperation with a base element forms a cavity in a shape corresponding to the space occupied by a semiconductor die; bonding a semiconductor die to a substrate to form an electrical connection; forming a second electrical contact to the die; preparing a soft pliable material, or ‘gel’, partly comprising a phosphor or phosphor like composition; putting the gel between the semiconductor die and the cover element; and pushing the cover element onto the substrate via indexing and coupling systems thus causing gel to take the shape of the cavity which encloses it and to come into forced intimate contact with the cover element and semiconductor die.

The forming a cover element step includes forming one in a molding process of hard plastic material such as polycarbonate whereby an undersurface in a shape which corresponds to space occupied by at least one semiconductor die is created.

These methods also include pushing the cover onto the substrate thus engaging a mechanical interlocking indexing means so that the cover element is tightly coupled to and aligned with the substrate. Further, that the gel is forced between the undersurface of the cover element and the substrate/semiconductor die combination to provides optical contact between said semiconductor die and gel, and said undersurface and gel.

One will now fully appreciate how white light LEDs can be made whereby the device packaging includes a self dosing feature with respect to a wavelength shifting medium. Although the present invention has been described in considerable detail with clear and concise language and with reference to certain preferred versions thereof including the best mode anticipated by the inventor, other versions are possible. Therefore, the spirit and scope of the invention should not be limited by the description of the preferred versions contained therein, but rather by the claims appended hereto.

1) Methods of forming light emitting articles comprising the steps:
forming a cover element of transparent plastic having an undersurface which forms a partial cavity in a shape corresponding to a semiconductor die;
bonding at least one semiconductor die to a substrate to form an electrical connection;
forming a second electrical contact to the top of said die;
preparing a soft pliable material, or ‘gel’, partly comprising a phosphor or phosphor like composition;
putting said gel between said semiconductor die and said cover element; and
pushing said cover element onto said substrate thereby causing said soft flexible material to take the shape of the cavity which encloses it and to come into intimate contact with the cover element and semiconductor die.

2) Methods of claim 1, said step ‘forming a cover element’ further comprises forming a cover element of hard plastic material such as polycarbonate.

3) Methods of claim 2, said step ‘forming a cover element’ includes forming the cover element in a molding process.

4) Methods of claim 1, said step ‘forming a cover element’ further comprises forming an undersurface in a shape which corresponds to space occupied by at least one semiconductor die whereby a cavity of similar shape is formed when said cover element is brought to said semiconductor die.

5) Methods of claim 1, said step ‘pushing said cover onto said substrate’ includes engaging a mechanical interlocking indexing means whereby the cover element is tightly coupled to and aligned with said substrate.

6) Methods of claim of 5, said gel is forced between the undersurface of the cover element and the substrate/semiconductor die combination to provides optical contact between said semiconductor die and gel, and said undersurface and gel.

7) Methods of forming light emitting articles comprising the steps:
mold forming a cover element of transparent plastic having an undersurface which forms a cavity in a shape which cooperates with an irradiance pattern formed as output of a semiconductor die;
bonding at least one semiconductor die to a substrate surface;
preparing a soft pliable binder material, or ‘gel’, partly comprising a wavelength shiffing composition;
filling said cavity with said gel; and
placing said cover element onto said substrate.

8) Methods of claim 7, said undersurface shaped is formed in consideration of the irradiance pattern whereby the light intensity and path length provide an interaction cross section with the wavelength shifting medium to provide a system output of high angular uniformity.

9) Methods of claim 7, said semiconductor is bonded to said substrate whereby when they are brought together the semiconductor is contained and aligned within said cavity.

10) Methods of claim 7, said placing step is performed whereby said soft flexible material is forced to take the shape of the cavity as defined by its undersurface.

11) Methods of claim 7, said filling step includes slightly over filling the cavity whereby excess material tends to assure the cavity well filled and air voids are omitted from the system.
